(19) United States
(12) Patent Application Publication
(10) Pub. No.: US 2026/0044635 A1
(43) Pub. Date: Feb. 12, 2026

(54) METHOD FOR GENERATING TRAINING DATA OF THREE-DIMENSIONAL SHAPE

(71) Applicant: TOYOTA JIDOSHA KABUSHIKI KAISHA, Toyota-shi (JP)

(72) Inventors: Hisanori KOBAYASHI, Nagakute-shi (JP); Kodai Goto, Miyoshi-shi (JP)

(73) Assignee: TOYOTA JIDOSHA KABUSHIKI KAISHA, Toyota-shi (JP)

(21) Appl. No.: 19/069,892

(22) Filed: Mar. 4, 2025

(30) Foreign Application Priority Data
Aug. 7, 2024 (JP) 2024-130889

(51) Int. Cl. G06F 30/12

(52) U.S. Cl. CPC G06F 30/12

(57) ABSTRACT

A method for generating training data for learning a three-dimensional shape of a recognition target includes: acquiring CAD data of the three-dimensional shape by a 3D CAD data acquisition unit; and converting the CAD data of the three-dimensional shape acquired by the 3D CAD data acquisition unit to STEP AP242 by a language expression conversion unit 3 to generate training data of the three-dimensional shape. It is therefore possible to implement a generative AI technique for 3D CAD that can understand, with high accuracy, even complex 3D CAD data and generate a three-dimensional model according to precise instructions.

### CROSS-REFERENCE TO RELATED APPLICATION

This application claims priority to Japanese Patent Application No. 2024-130889 filed on Aug. 7, 2024. The disclosure of the above-identified application, including the specification, drawings, and claims, is incorporated by reference herein in its entirety.

### BACKGROUND

### 1. Technical Field

The present disclosure relates to methods for generating training data of a three-dimensional shape. More particularly, the present disclosure relates to a measure to accurately learn the shape of an object having a three-dimensional shape (object to be recognized; hereinafter referred to as “recognition target”).

### 2. Description of Related Art

Various methods for constructing a three-dimensional model (3D model) have been conventionally proposed. For example, WO2008/127254 discloses a computer-aided design (CAD) system intended to more quickly update a three-dimensional model. The system generates a three-dimensional model. The system modifies one of a plurality of components. The system determines other ones of the plurality of components that possibly change the three-dimensional model as a result of modifying the one component. The system updates the three-dimensional model by regenerating the other components determined to possibly change the three-dimensional model and not regenerating the remainder of the plurality of components that does not possibly change the three-dimensional model.

### SUMMARY

Conventional generative artificial intelligence (AI) techniques can create textual summaries and reports, generate various images and videos, and program. However, very few generative AI techniques for three-dimensional shapes have been developed.

In other words, in learning of a three-dimensional shape (3D shape) by AI, features and patterns are extracted from visual information such as an image or a video, and the three-dimensional shape is identified from the features and the patterns. Therefore, it is possible to recognize a three-dimensional shape from an image and identify the type of the three-dimensional shape or its unusual features from the image.

However, there is vagueness in recognition of a three-dimensional shape by AI, and it has not been possible to recognize, with high accuracy, a three-dimensional shape. As a result, it has not been possible to implement a generative AI technique for 3D CAD that can understand, with high accuracy, complex 3D CAD data and generate a three-dimensional model according to precise instructions.

The present disclosure was made in view of the above circumstances. An object of the present disclosure is to provide a method for generating training data of a three-dimensional shape that can implement a generative AI technique for 3D CAD that can understand, with high accuracy, complex 3D CAD data and generate a three-dimensional model according to precise instructions.

In order to achieve the above object, the present disclosure provides a method for generating training data for learning a three-dimensional shape of a recognition target. The method includes:
acquiring CAD data of the three-dimensional shape; and
converting the acquired CAD data of the three-dimensional shape to a predetermined protocol to generate training data of the three-dimensional shape.

According to this matter specifying the disclosure, converting the CAD data to the predetermined protocol allows AI to learn the three-dimensional shape of the recognition target based on the training data generated by the protocol. It is therefore possible to implement a generative AI technique for 3D CAD that can understand, with high accuracy, even complex 3D CAD data and generate a three-dimensional model according to precise instructions.

Specifically, the converting may convert the CAD data of the three-dimensional shape to a protocol constructed by a language expression.

The three-dimensional shape is identified by the protocol constructed by the language expression. This allows AI to learn (learn from the language) the three-dimensional shape of the recognition target with high accuracy. It is therefore possible to implement a generative AI technique for 3D CAD that can understand, with high accuracy, even complex 3D CAD data and generate a three-dimensional model according to precise instructions.

The three-dimensional shape of the recognition target may be comprised of a plurality of parts.

The method may further include reflecting a definition of the parts when converting the CAD data of the three-dimensional shape to the predetermined protocol.

It is therefore possible to implement a generative AI technique for 3D CAD that can understand, with high accuracy, even a complex three-dimensional shape of a recognition target comprised of a plurality of parts and generate a three-dimensional model according to precise instructions.

The definition of the parts may be given by annotating each of the parts.

It is therefore possible to give AI an accurate instruction corresponding to each part when executing a prompt for each part.

In the present disclosure, the method for generating training data for learning a three-dimensional shape of a recognition target includes acquiring CAD data of the three-dimensional shape. The method further includes converting the acquired CAD data of the three-dimensional shape to a predetermined protocol to generate training data of the three-dimensional shape. It is therefore possible to implement a generative AI technique for 3D CAD that can understand, with high accuracy, even complex 3D CAD data and generate a three-dimensional model according to precise instructions.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a block diagram illustrating an outline of a three-dimensional shape recognition support system according to an embodiment;

FIG. 2 is a diagram for describing a process of learning 3D CAD in the embodiment;

FIG. 3 is a diagram for describing a process of associating three-dimensional shapes and parts in the embodiment; and

FIG. 4 is a diagram for explaining a 3D model generating process at the time of executing a prompt according to the embodiment.

### DETAILED DESCRIPTION OF EMBODIMENTS

Hereinafter, an embodiment of the present disclosure will be described with reference to the drawings. In the present embodiment, a case will be described in which a three-dimensional shape recognition support system to be described later is provided with a functional unit that implements the three-dimensional shape training data generation method according to the present disclosure. The configuration for implementing the training data generation method of the three-dimensional shape is not limited to this.

### Overview of Three-Dimensional Shape Recognition Support System

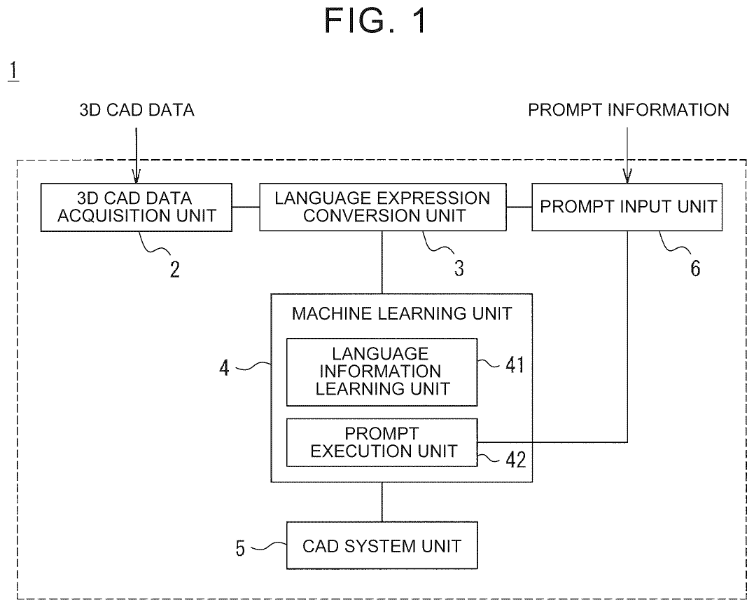

FIG. 1 is a block diagram schematically illustrating a three-dimensional shape recognition support system 1 including a functional unit that performs a three-dimensional shape training data generation method according to the present disclosure.

As illustrated in FIG. 1, the three-dimensional shape recognition support system 1 according to the present embodiment includes a 3D CAD data acquisition unit 2, a language expression conversion unit 3, a machine learning unit (AI) 4, a CAD system unit 5, and a prompt input unit 6. The machine learning unit 4 includes a language information learning unit 41 and a prompt execution unit 42. The configuration of the three-dimensional shape recognition support system 1 is not limited to this.

### 3D CAD Data Acquisition Unit

The 3D CAD data acquisition unit 2 is a functional unit that acquires 3D CAD data of a recognition target (e.g., a vehicle body of an automobile) whose three-dimensional shape needs to be recognized with high accuracy. The 3D CAD data is input from the external device to the three-dimensional shape recognition support system 1 by an operator's manipulation of the data created by the external device, for example. The operation of acquiring 3D CAD data by the 3D CAD data acquisition unit 2 corresponds to “acquiring CAD data of the three-dimensional shape.”

### Language Expression Conversion Unit

The language expression conversion unit 3 is a functional unit that receives 3D CAD data acquired by the 3D CAD data acquisition unit 2 and converts the 3D CAD data to a language expression of a STEP (Standard for the Exchange of Product Data) AP242 which is a ISO standard.

Specifically, for example, a EXPRESS modeling language is used as the language expression. This EXPRESS modeling language is a formal specification language prepared to formally describe product model information in STEP (international standard regarding external expressions of product models, which is discussed by ISO Technical Committee 184, Subcommittee 4). Further, the language expression may include 3D model data stored in a ASCII text format.

The information (3D language information) of STEP AP242 converted from 3D CAD data as described above is used as training data for learning the shape of the recognition target in the machine learning unit 4 described later. The operation of conversion to the language expression in the language expression conversion unit 3 corresponds to “converting the acquired CAD data of the three-dimensional shape to a predetermined protocol to generate training data of the three-dimensional shape,” and “converting the CAD data of the three-dimensional shape to a protocol constructed by a language expression.”

For STEP AP242, more specifically, as is known, a standard for data exchange, also called ISO10303, is an exchange standard for ISO standards (standard for image data exchange). The 3D model data of STEP AP242 is constructed by text (language expression) that can be interpreted by various CAD systems. By using this STEP AP242, it is possible to easily create, share, and edit a 3D model by various programs and software.

The reason for using STEP AP242 as the conversion target standard is that STEP AP242 is compatible with various CAD tools/software, and thus can be easily shared and edited as described above. In addition, it is possible to store data accurately by using a NURBS curve which mathematically represents a curve. In addition, it is easy to customize, and it is easy to store the backup on another computer.

In the present embodiment, STEP AP242 is used as the conversion target standard. The present disclosure is not limited thereto, and may be converted to STEP AP203, STEP AP214, IGES (Initial Graphics Exchange Specification) or STL (Stereolithography, Standard Triangle Language).

STEP AP203 is known to define components, the geometry, topology, and configuration control of the solid model of the assembly.

STEP AP214 is also known to encompass all of the information contained in STEP AP203, as well as information on color layers, design intent, and geometric dimensional tolerances.

IGES is a file format of CAD intermediate data conforming to IGES standard, and is known as a ASCII text file composed of 80 characters per line.

Furthermore, STL describes a set of small triangular elements constituting a three-dimensional shape, and is known to exist in a ASCIISTL format and a binary STL format described in plaintext.

In the present embodiment, as described above, STEP AP242, STEP AP203, STEP AP214, IGES and STL are exemplified as standards to be converted from 3D CAD data. The present disclosure is not limited thereto. Any standard can be applied as long as it can be replaced with a language expression that makes it easier for AI to understand a three-dimensional shape.

### Language Information Learning Unit

The language information learning unit 41 of the machine learning unit 4 has a function of learning the shape of the recognition target precisely and accurately based on information of a given language expression (information converted to STEP AP242 described above). In other words, 3D CAD data is recognized as the training data using the information of the language expression that is easy for AI to understand. As a result, the machine learning unit 4 can precisely and accurately learn the shape (the shape of the recognition target) related to 3D CAD data with high accuracy even when the 3D CAD data is complex data. For this reason, vagueness in recognition of the three-dimensional shape by AI so far is eliminated, and the three-dimensional shape of the recognition target can be recognized with high accuracy.

### Prompt Execution Unit

As will be described later, the prompt execution unit 42 of the machine learning unit 4 has a function of performing image processing corresponding to a prompt on a recognition target whose shape is learned precisely and accurately by the language information learning unit 41 when a prompt (instruction) is input from the prompt input unit 6. Examples of the prompt include various types of prompts such as a change in an outer edge shape of a recognition target, a change in a size of each part on the recognition target, a change in a position of each part on the recognition target, and a change in a color of each part on the recognition target.

### CAD System Unit

As one of the functions, the CAD system unit 5 has a function of defining, by annotations, respective parts in the shape of the recognition target obtained by the learning. Also in this annotation, it is converted as the information of the language expression. The conversion to a language expression is also performed in the same manner as the conversion described above (for example, conversion to STEP AP242), and therefore, the explanation thereof is omitted here.

Also in this conversion, the standard of the conversion destination is not limited to STEP AP242. It may be converted to STEP AP203, STEP AP214, IGES, or STL. Further, the present disclosure is not limited thereto, and any AI can be applied as long as it is a standard that can be replaced with a language expression that is easy to understand the three-dimensional shape etc. of each part in the shape of the recognition target.

As a result, in the machine learning unit 4 (language information learning unit 41), the shape of the recognition target and each part (information such as position, size, and shape of each part) are linked and learned. For this reason, the annotation using the function of the CAD system unit 5 corresponds to “reflecting a definition of the parts when converting the CAD data of the three-dimensional shape to the predetermined protocol.”

In the present embodiment, the shape of the recognition target is associated with each part by annotation using the function of the CAD system unit 5, but the shape of the recognition target may be associated with each part by other means.

### Prompt Input Unit

The prompt input unit 6 is a functional unit that inputs instruction information such as a shape of a recognition target and a change of each part by an operator. For example, when a hole is present in the recognition target, a prompt such as changing the position of the hole is input.

### Example of Application to Recognition of Vehicle Body Shape

Next, an example of a specific usage mode of the three-dimensional shape recognition support system 1 configured as described above will be described. Here, a 3D model in which 3D CAD data of the vehicle body of the vehicle is learned by AI and the position of the hole drawn on a part of the vehicle body is moved to the front side of the vehicle body by a predetermined dimension (instructed dimension) is generated as a prompt. Examples of the prompt include, but are not limited to, various instructions such as a change in the size of each part on the vehicle body of the automobile, a change in the position of each part on the recognition target, and a change in the color of each part on the recognition target.

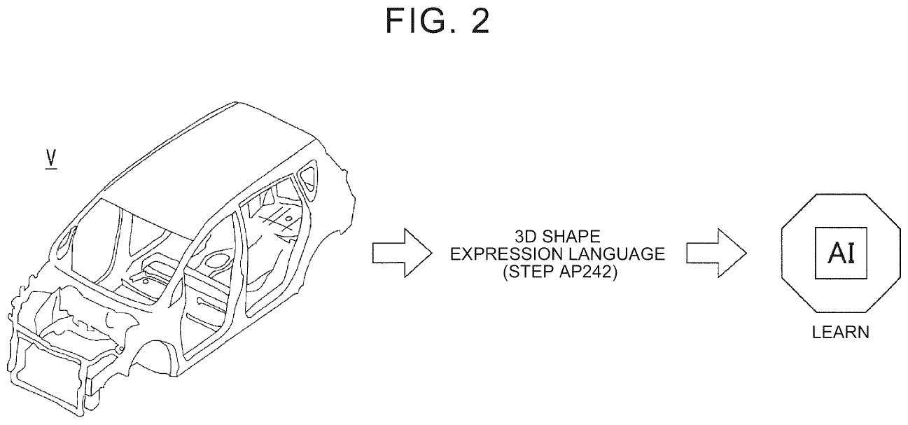

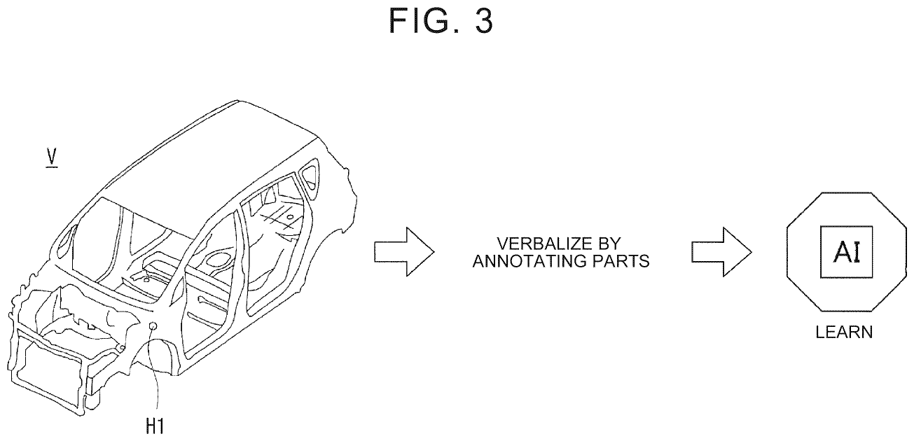

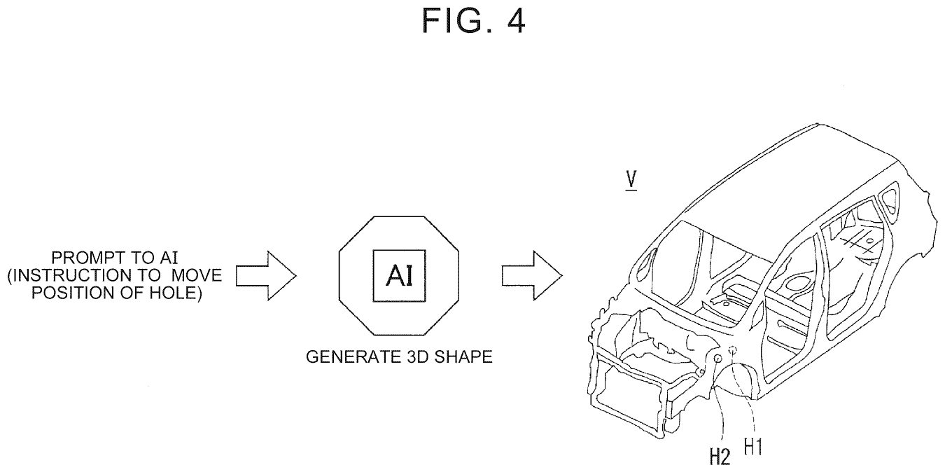

FIG. 2 is a diagram illustrating a process of learning 3D CAD data. FIG. 3 is a diagram illustrating a process of associating a three-dimensional shape and a part (here, the position of a hole), and FIG. 4 is a diagram illustrating a process of generating a 3D model at the time of executing a prompt.

First, in the process of learning 3D CAD data, as shown in FIG. 2, 3D CAD data of the vehicle body V is acquired by 3D CAD data acquisition unit 2 (see FIG. 1). This 3D CAD data is converted to a STEP AP242 language expression (3D shape expression language) by the language expression conversion unit 3.

Then, the language information learning unit 41 of the machine learning unit 4 precisely and accurately learns (learn from a language) the three-dimensional shape of the vehicle body V based on STEP AP242 that is 3D shape expression language.

In the process of linking the three-dimensional shape with the position of the hole, as illustrated in FIG. 3, each part in the shape of the vehicle body V is defined by an annotation by the function of the CAD system unit 5 (information such as the position and shape of each part is verbalized by the annotation). Thus, in the machine learning unit 4, the three-dimensional shape of the vehicle body V and each part are associated with each other with high accuracy. In particular, the position of the hole H1 formed on the front fender inner panel of the vehicle body V (the positions on the X-axis, the Y-axis, and the Z-axis respectively) is linked to the shape of the vehicle body V with high accuracy.

When a prompt is issued to change the position of the hole H1 in a design change etc., as shown in FIG. 4, information on the prompt (in this case, an instruction to move the position of the hole) is input to AI. In FIG. 4, information on the prompt to move the position of the hole formed on the front fender inner panel of the vehicle body V from the position of H1 in the drawing (the position indicated by the broken line) to the position of H2 in the drawing (position indicated by continuous line) is input to AI. Examples of the information on the prompt input to AI include information for identifying a hole (part on 3D CAD data), a direction in which the hole is moved (such as moving distances on the X-axis, the Y-axis, and the Z-axis).

The AI that has received the information on the prompt generates a 3D model to move the position of the hole on the front fender inner panel of the vehicle body V from H1 position to H2 position. As described above, the three-dimensional shape of the vehicle body V is precisely and accurately learned using STEP AP242 that is a 3D shape expression language as the training data. By defining each part in the shape of the vehicle body V by annotation, each part is associated with the shape of the vehicle body V with high accuracy. Therefore, the position of the hole H1 is recognized with high accuracy. The amount of movement (amount of movement from the hole H1 to the hole H2) according to the information on the prompt can also be obtained from the position with high accuracy. Therefore, the generated 3D model is obtained as a faithfully reproduced prompt.

### Effects of Embodiment

As described above, in the present embodiment, acquired 3D CAD data is converted to STEP AP242 to generate training data of a three-dimensional shape of a recognition target. As a result, the machine learning unit 4 can learn the three-dimensional shape of the recognition target based on the training data generated by the STEP AP242. It is therefore possible to implement a generative AI technique for 3D CAD that can understand, with high accuracy, even complex 3D CAD data and generate a three-dimensional model according to precise instructions. In particular, since STEP AP242 is constructed by language expressions, the machine learning unit 4 can learn, with high accuracy, the three-dimensional shape of the recognition target.

In the present embodiment, when 3D CAD is converted, the step of reflecting the definition of the part of the recognition target is performed. It is therefore possible to implement a generative AI technique for 3D CAD that can understand, with high accuracy, even a complex three-dimensional shape of a recognition target comprised of a plurality of parts and generate a three-dimensional model according to precise instructions. In particular, since the definition of the plurality of parts is performed by performing annotation for each part, when the prompt for each part is executed, an accurate instruction corresponding to the part can be given to the machine learning unit 4.

### Other Embodiments

It should be noted that the present disclosure is not limited to the embodiment above, and all modifications and applications included in the scope of claims and a range equivalent to the scope of claims are possible.

For example, in the above embodiment, 3D CAD data of the vehicle body V of the vehicle is learned by AI, and a 3D model in which the position of the hole H1 of the vehicle body V is moved to the front side of the vehicle body by a predetermined dimension is generated as a prompt. The present disclosure is not limited to this, and may be applied to a case where a 3D is generated by prompting the vehicle body V to another part.

In addition, not only 3D CAD data of the vehicle body V of the vehicle but also 3D CAD data of various objects (recognition targets) can be targeted.

For example, the automatic generation of 3D model can be applied when the automatic generation of 3D model of the production line of the plant is performed. Further, the present disclosure can be applied to a case where an 3D model of a building such as a building or a house is automatically generated, a case where an 3D model of an electric device such as a smart phone or a television is automatically generated, and the like.

The present disclosure can also be applied to assignment of operations related to a 3D model. For example, the present disclosure can be applied to automation of assignment of an assembling operation by a worker or a producer robot in a factory corresponding to 3D CAD data of vehicles. It can also be applied to automation of checking of laws, production requirements, safety requirements, etc. on the assumption of 3D CAD data of vehicles and production facilities.

The present disclosure is applicable to a method for generating training data of a three-dimensional shape that can be used to design a vehicle body etc.

What is claimed is:

1. A method for generating training data for learning a three-dimensional shape of a recognition target, the method comprising:
acquiring CAD data of the three-dimensional shape; and
converting the acquired CAD data of the three-dimensional shape to a predetermined protocol to generate training data of the three-dimensional shape.

2. The method according to claim 1, wherein the converting converts the CAD data of the three-dimensional shape to a protocol constructed by a language expression.

3. The method according to claim 1, wherein:
the three-dimensional shape of the recognition target is comprised of a plurality of parts; and
the method further includes reflecting a definition of the parts when converting the CAD data of the three-dimensional shape to the predetermined protocol.

4. The method according to claim 3, wherein the definition of the parts is given by annotating each of the parts.
